(19) United States
(12) Patent Application Publication
(10) Pub. No.: US 2026/0260851 A1
(43) Pub. Date: Sep. 3, 2026

(54) PLASMA PROCESSING APPARATUS, METHOD OF MANUFACTURING ELECTRODE PLATE, AND METHOD OF REGENERATING ELECTRODE PLATE

(71) Applicant: Tokyo Electron Limited, Tokyo (JP)

(72) Inventors: Takuya HARASHIMA, Miyagi (JP); Naokazu FURUYA, Miyagi (JP)

(21) Appl. No.: 19/655,127

(22) Filed: Apr. 22, 2026

Related U.S. Application Data
(63) Continuation of application No. PCT/JP2024/038688, filed on Oct. 30, 2024.

(30) Foreign Application Priority Data
Nov. 6, 2023 (JP) 2023-189188

(51) Int. Cl. H01J 37/32; H01J 9/26

(52) U.S. Cl. CPC H01J 37/32449; H01J 9/265; H01J 37/32467; H01J 2237/002

(57) ABSTRACT

A plasma processing apparatus includes an electrode plate disposed to face a substrate mounting table across a processing space, wherein the electrode plate includes: a first plate that is composed of silicon and in which a refrigerant flow path is formed; and a second plate that is composed of silicon and in which a buffer chamber configured to supply a processing gas into the processing space is provided, and wherein the electrode plate is formed integrally by joining the first plate and the second plate.

### CROSS-REFERENCE TO RELATED APPLICATIONS

This application is a continuation application of International Application No. PCT/JP2024/038688, filed on October 30, 2024, and designating the U.S., which is based upon and claims priority to Japanese Patent Application No. 2023-189188, filed on November 6, 2023, the entire contents of which are incorporated herein by reference.

### TECHNICAL FIELD

The present disclosure relates to a plasma processing apparatus, a method of manufacturing an electrode plate, and a method of regenerating an electrode plate.

### BACKGROUND ART

For example, Japanese Patent Application Laid-Open Publication No. 2012-216607 discloses a ceiling electrode plate that is suspended by an electrode support including a temperature adjusting mechanism, contacts the electrode support via a cooling plate, and includes a heat conduction sheet on the surface contacting the cooling plate.

### SUMMARY

According to one aspect of the present disclosure, a plasma processing apparatus is provided, including an electrode plate disposed to face a substrate mounting table across a processing space, wherein the electrode plate includes: a first plate that is composed of silicon and in which a refrigerant flow path is formed; and a second plate that is composed of silicon and in which a buffer chamber configured to supply a processing gas into the processing space is provided, wherein the electrode plate is formed integrally by joining the first plate and the second plate.

### BRIEF DESCRIPTION OF THE DRAWINGS

FIG. 1 is a diagram illustrating a configuration of a plasma processing system including a plasma processing apparatus according to the present embodiment;

FIG. 2 is a cross-sectional view illustrating a showerhead of the plasma processing apparatus according to the present embodiment;

FIG. 3 is a flowchart illustrating a method of manufacturing a showerhead in the plasma processing apparatus according to the present embodiment;

FIG. 4 is a cross-sectional view (part 1) illustrating a first plate forming step of the method of manufacturing a showerhead in the plasma processing apparatus according to the present embodiment;

FIG. 5 is a cross-sectional view (part 2) illustrating the first plate forming step of the method of manufacturing a showerhead in the plasma processing apparatus according to the present embodiment;

FIG. 6 is a cross-sectional view (part 1) illustrating a second plate forming step of the method of manufacturing a showerhead in the plasma processing apparatus according to the present embodiment;

FIG. 7 is a cross-sectional view (part 2) illustrating the second plate forming step of the method of manufacturing a showerhead in the plasma processing apparatus according to the present embodiment;

FIG. 8 is a cross-sectional view illustrating a joining step of the method of manufacturing a showerhead in the plasma processing apparatus according to the present embodiment;

FIG. 9 is a cross-sectional view illustrating a worn showerhead of the plasma processing apparatus according to the present embodiment;

FIG. 10 is a flowchart illustrating a method of regenerating a showerhead in the plasma processing apparatus according to the present embodiment;

FIG. 11 is a cross-sectional view (part 1) illustrating the method of regenerating a showerhead in the plasma processing apparatus according to the present embodiment;

FIG. 12 is a cross-sectional view (part 2) illustrating the method of regenerating a showerhead in the plasma processing apparatus according to the present embodiment; and

FIG. 13 is a cross-sectional view (part 3) illustrating the method of regenerating a showerhead in the plasma processing apparatus according to the present embodiment.

### DETAILED DESCRIPTION OF THE INVENTION

Embodiments of the present disclosure will be described below with reference to the drawings. In the present specification and the drawings, the same reference numerals are used to denote substantially the same components, thereby omitting redundant descriptions. In order to facilitate understanding, the components in the drawings may not be to scale. For directions, such as parallel, right angle, orthogonal, horizontal, perpendicular, upper-lower, left-right, and such directions, a degree of deviation that does not impair the effect of the embodiment is allowed. The shape of a corner part is not limited to a right-angle part, and may be rounded. The parallel, right angle, orthogonal, horizontal, and perpendicular directions may include approximately parallel, approximately right angle, approximately orthogonal, approximately horizontal, and approximately perpendicular directions.

### Plasma Processing System

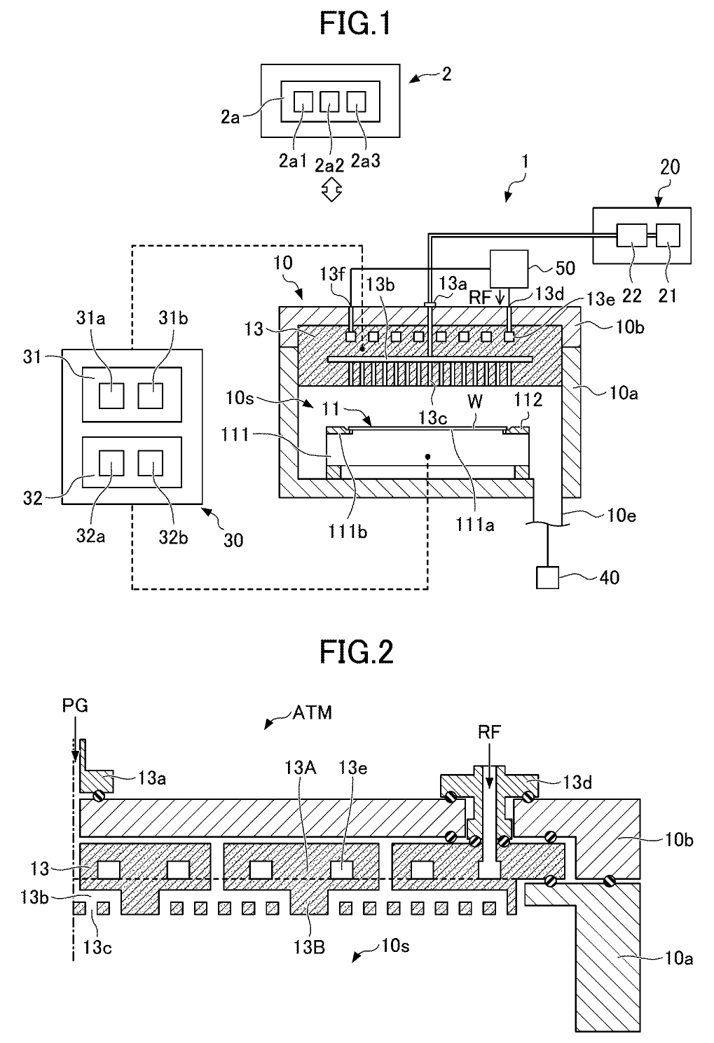

Hereinafter, an example of the configuration of a plasma processing system will be described. FIG. 1 is a diagram illustrating the configuration of the plasma processing system including a plasma processing apparatus 1, which is an example of a plasma processing apparatus according to the present embodiment.

The plasma processing system includes a capacitively coupled plasma processing apparatus 1 and a controller 2. The capacitively coupled plasma processing apparatus 1 includes a plasma processing chamber 10, a gas supply 20, a power source 30, a gas exhaust system 40, and a heat transfer fluid supply 50. The plasma processing apparatus 1 also includes a substrate support 11 and a gas inlet. The gas inlet is configured to introduce at least one processing gas into the plasma processing chamber 10. The gas inlet includes a showerhead 13. The substrate support 11 is disposed in the plasma processing chamber 10. The showerhead 13 is disposed above the substrate support 11. In one embodiment, the showerhead 13 constitutes at least a part of the ceiling of the plasma processing chamber 10. The plasma processing chamber 10 includes a plasma processing space 10s defined by the showerhead 13, a side wall 10a of the plasma processing chamber 10, and the substrate support 11. The plasma processing chamber 10 includes at least one gas supply port for supplying at least one processing gas into the plasma processing space 10s, and at least one gas exhaust port for exhausting a gas from the plasma processing space. The side wall 10a is grounded. The plasma processing chamber 10 includes an upper wall 10b to cover the showerhead 13 from above. The showerhead 13 and the substrate support 11 are electrically insulated from the housing of the plasma processing chamber 10.

The substrate support 11 includes a body part 111 and a ring assembly 112. The body part 111 has a center region (substrate support surface) 111a for supporting a substrate (wafer) W and an annular region (ring support surface) 111b for supporting the ring assembly 112. The annular region 111b of the body part 111 surrounds the center region 111a of the body part 111 in a plan view. The substrate W is disposed on the center region 111a of the body part 111, and the ring assembly 112 is disposed on the annular region 111b of the body part 111 to surround the substrate Won the center region 111a of the body part 111. In one embodiment, the body part 111 includes a base and an electrostatic chuck. The base includes a conductive member. The conductive member of the base serves as a lower electrode. The electrostatic chuck is disposed on the base. The upper surface of the electrostatic chuck has the substrate support surface 111a. The ring assembly 112 includes one or a plurality of annular members. At least one of the one or the plurality of annular members is an edge ring. Although not shown, the substrate support 11 may include a temperature control module configured to control at least one of the electrostatic chucks, the ring assembly 112, or the substrate to a target temperature. The temperature control module may include a heater, a heat transfer medium, or a flow path, or a combination thereof. A heat transfer fluid, such as brine or gas, flows through the flow path. The substrate support 11 may also include a heat transfer gas supply configured to supply a heat transfer gas between the back surface of the substrate W and the substrate support surface 111a.

The showerhead 13 is configured to introduce at least one processing gas from the gas supply 20 into the plasma processing space 10s. The showerhead 13 is disposed to face the substrate support 11 (substrate support base) across the plasma processing space 10s. The showerhead 13 includes at least one gas supply port 13a, at least one gas diffusion chamber 13b, a plurality of gas introduction ports 13c, a heat transfer fluid inlet port 13d, a fluid flow path 13e, and a heat transfer fluid outlet port 13f. The processing gas supplied to the gas supply port 13a passes through the gas diffusion chamber 13b and is introduced into the plasma processing space 10s through the plurality of gas inlet ports 13c. The showerhead 13 also includes a conductive member. The showerhead 13 is composed of silicon. The conductive member of the showerhead 13 functions as an upper electrode. A heat transfer fluid RF supplied from the heat transfer fluid supply 50 flows from the heat transfer fluid inlet port 13d into the fluid flow path 13e in the showerhead 13. The heat transfer fluid RF cools the showerhead 13 while flowing through the fluid flow path 13e. The heat transfer fluid RF that has flowed through the fluid flow path 13e is discharged from the heat transfer fluid outlet port 13f into the heat transfer fluid supply 50. The fluid flow path 13e is, for example, spirally formed in the showerhead 13 from the heat transfer fluid inlet port 13d to the heat transfer fluid outlet port 13f. The fluid flow path 13e is an example of a refrigerant flow path. The heat transfer fluid RF is, for example, brine and the like. The gas inlet may include, in addition to the showerhead 13, one or a plurality of side gas injectors (SGI) attached to one, or a plurality of openings formed in the side wall 10a.

The gas supply 20 may include at least one gas source 21 and at least one flow rate controller 22. In one embodiment, the gas supply 20 is configured to supply at least one processing gas from a corresponding gas source 21 to the showerhead 13 via a corresponding flow rate controller 22. Each flow rate controller 22 may include, for example, a mass flow controller or a pressure controlled-flow rate controller. In addition, the gas supply 20 may include one or more flow rate modulation devices that modulate the flow rate of the at least one processing gas or pulse the at least one processing gas.

The power supply 30 includes an RF power source 31 coupled to the plasma processing chamber 10 via at least one impedance matching circuit. The RF power source 31 is configured to supply at least one RF signal (RF power), such as a source RF signal and a bias RF signal, to the conductive member of the substrate support 11 and/or the conductive member of the showerhead 13. As a result, a plasma is formed from at least one processing gas supplied into the plasma processing space 10s. Thus, the RF power source 31 may function as at least a part of a plasma former configured to form a plasma from one or more processing gases in the plasma processing chamber 10. Further, when a bias RF signal is supplied to the conductive member of the substrate support 11, a bias potential is generated in the substrate W, which enables an ionic component in the formed plasma to be drawn into the substrate W.

In one embodiment, the RF power source 31 includes a first RF generator 31a and a second RF generator 31b. The first RF generator 31a is coupled to the conductive member of the substrate support 11 and/or the conductive member of the showerhead 13 via at least one impedance matching circuit and is configured to generate a source RF signal (source RF power) for plasma formation. In one embodiment, the source RF signal has a frequency in the range of 13 MHz to 150 MHz. In one embodiment, the first RF generator 31a may be configured to generate a plurality of source RF signals having different frequencies. The generated one or plurality of source RF signals are supplied to the conductive member of the substrate support 11 and/or the conductive member of the showerhead 13. The second RF generator 31b is coupled to the conductive member of the substrate support 11 via at least one impedance matching circuit and is configured to generate a bias RF signal (bias RF power). In one embodiment, the bias RF signal has a lower frequency than the source RF signal. In one embodiment, the bias RF signal has a frequency in the range of 400 kHz to 13.56 MHz. In one embodiment, the second RF generator 31b may be configured to generate a plurality of bias RF signals having different frequencies. The generated one or plurality of bias RF signals are supplied to the conductive member of the substrate support 11. Further, in various embodiments, at least one of the source RF signals or the bias RF signal may be pulsed.

The power supply 30 may also include a DC power supply 32 coupled to the plasma processing chamber 10. The DC power supply 32 includes a first DC generator 32a and a second DC generator 32b. In one embodiment, the first DC generator 32a is connected to the conductive member of the substrate support 11 and is configured to generate a first DC signal. The generated first bias DC signal is applied to the conductive member of the substrate support 11. In one embodiment, the first DC signal may be applied to another electrode, such as an electrode in the electrostatic chuck. In one embodiment, the second DC generator 32b is connected to the conductive member of the showerhead 13 and is configured to generate a second DC signal. The generated second DC signal is applied to the conductive member of the showerhead 13. In various embodiments, at least one of the first DC signal or the second DC signal may be pulsed. The first and second DC generators 32a and 32b may be provided in addition to the RF power source 31, and the first DC generator 32a may be provided in place of the second RF generator 31b.

The gas exhaust system 40 may be connected, for example, to a gas outlet 10e provided on the bottom of the plasma processing chamber 10. The gas exhaust system 40 may include a pressure regulating valve and a vacuum pump. The pressure in the plasma processing space 10s is regulated by the pressure regulating valve. The vacuum pump may include a turbomolecular pump, a dry pump, or a combination thereof.

The heat transfer fluid supply 50 supplies a cooled heat transfer fluid RF to the showerhead 13. The heat transfer fluid supply 50 also recovers the heat transfer fluid RF heated in the showerhead 13. The heat transfer fluid supply 50 then cools the recovered heat transfer fluid RF.

The controller 2 processes computer-executable instructions for causing the plasma processing apparatus 1 to perform various steps to be described herein. The controller 2 may be configured to control the components of the plasma processing apparatus 1 to perform the various steps to be described herein. In one embodiment, part or the entirety of the controller 2 may be included in the plasma processing apparatus 1. The controller 2 may include, for example, a computer 2a. The computer 2a may include, for example, a processor (Central Processing Unit (CPU)) 2a1, a storage unit 2a2, and a communication interface 2a3. The processor 2a1 may be configured to execute various control operations based on a program stored in the storage unit 2a2. The storage unit 2a2 may include a Random Access Memory (RAM), a Read Only Memory (ROM), a Hard Disk Drive (HDD), or a Solid-State Drive (SSD), or a combination thereof. The communication interface 2a3 may communicate with the plasma processing apparatus 1 via a communication line, such as a Local Area Network (LAN) and the like.

The plasma processing apparatus according to the present embodiment will be described. The plasma processing apparatus according to the present embodiment includes an electrode plate disposed to face the substrate mounting table across the processing space. The electrode plate in the plasma processing apparatus according to the present embodiment includes a first plate that is composed of silicon and in which a refrigerant flow path is formed, and a second plate that is composed of silicon and in which a buffer chamber for supplying a processing gas into the processing space is formed. The electrode plate of the plasma processing apparatus according to the present embodiment is formed integrally by joining the first plate and the second plate.

The electrode plate of the plasma processing apparatus according to the present embodiment will be described in detail with reference to FIG. 2. FIG. 2 is a diagram illustrating the showerhead 13, which is an example of the electrode plate of the plasma processing apparatus 1, which is an example of the plasma processing apparatus according to the present embodiment. Specifically, FIG. 2 is a cross-sectional view a region around the showerhead 13 in the plasma processing apparatus 1.

The plasma processing apparatus 1 includes the showerhead 13 as an example of the electrode plate. The showerhead 13 is formed integrally by joining a first plate 13A and a second plate 13B.

The first plate 13A is composed of silicon. The first plate 13A includes the fluid flow path 13e through which the heat transfer fluid RF flows. In other words, the fluid flow path 13e through which the heat transfer fluid RF flows is formed in the first plate 13A.

The second plate 13B is composed of silicon. The second plate 13B includes the gas diffusion chamber 13b, which is an example of the buffer chamber for supplying a processing gas PG into the plasma processing space 10s. In other words, the buffer chamber (gas diffusion chamber 13b) for supplying a processing gas PG into the processing space (plasma processing space 10s) is provided in the second plate 13B.

The first plate 13A and the second plate 13B are joined by being pressed at a low temperature (for example, normal temperature) while the surfaces to be joined are activated. Specifically, a silicon oxide layer is formed on the surface of the first plate 13A and joined with the silicon on the surface of the second plate 13B.

The side wall 10a and the upper wall 10b of the plasma processing apparatus 1 are provided to inhibit stress from being applied to the showerhead 13 due to a pressure difference when the plasma processing space 10s becomes a vacuum state when the outside of the plasma processing chamber 10 is at the atmospheric pressure ATM.

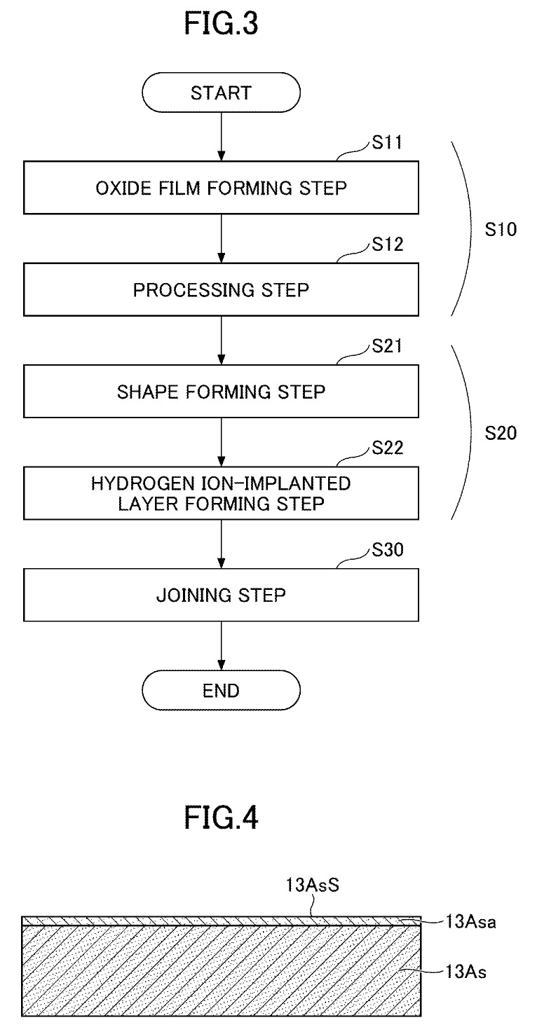

A method of manufacturing the showerhead 13 in the plasma processing apparatus 1, which is an example of the plasma processing apparatus according to the present embodiment, will be described. By describing the method of manufacturing the showerhead 13, the method of manufacturing the electrode plate in the plasma processing apparatus according to the present embodiment will be described. FIG. 3 is a flowchart explaining the method of manufacturing the showerhead 13 in the plasma processing apparatus 1, which is an example of the plasma processing apparatus according to the present embodiment.

The method of manufacturing the showerhead 13 includes a first plate forming step (step S10) of forming the first plate 13A and a second plate forming step (step S20) of forming the second plate 13B. The method of manufacturing the showerhead 13 also includes a joining step (step S30) of joining the first plate 13A and the second plate 13B.

(Step S10) First, the first plate 13A is formed (first plate forming step). The first plate forming step includes an oxide film forming step (step S11) and a processing step (step S12).

[Step S11] First, in the oxide film forming step, a silicon oxide film is formed on a silicon substrate composed of silicon. FIG. 4 is a cross-sectional view explaining the first plate forming step of the method of manufacturing the showerhead 13 in the plasma processing apparatus 1, which is an example of the plasma processing apparatus according to the present embodiment. Specifically, FIG. 4 is a view showing a process of forming a silicon oxide film on a silicon substrate.

In the oxide film forming step (step S11), the silicon oxide film 13Asa is formed on a surface 13AsS of the silicon substrate 13As composed of silicon. The silicon oxide film 13Asa is formed by, for example, thermal oxidation or the like.

[Step S12] Next, in the processing step, the silicon substrate on which the silicon oxide film is formed is processed to form a fluid flow path and a gas flow path. FIG. 5 is a cross-sectional view explaining the first plate forming step of the method of manufacturing the showerhead 13 in the plasma processing apparatus 1, which is an example of the plasma processing apparatus according to the present embodiment. FIG. 5 is a view showing the step of forming, by processing, the fluid flow path and the gas flow path in the silicon substrate on which the silicon oxide film is formed.

In the processing step (step S12), grooves 13Ag that become the fluid flow path 13e in the showerhead 13 are processed. Further, in the processing step (step S12), through-holes 13Ar leading to either the heat transfer fluid inlet port 13d or the heat transfer fluid outlet port 13f of the showerhead 13 are processed. Further, in the processing step (step S12), a through-hole 13Ah penetrating the first plate 13A and leading to the gas supply port 13a of the showerhead 13 is processed. The through-hole 13Ah constitutes a part of the gas flow path through which a processing gas is caused to flow into the gas diffusion chamber serving as the buffer chamber.

The processing performed in the processing step (step S12) may be, for example, etching or cutting.

When the process flow up to step S12 has been performed, the first plate 13A is formed. The surface of the silicon oxide film 13Aa remaining through the processing serves as a joining surface 13AS to be joined with the second plate 13B.

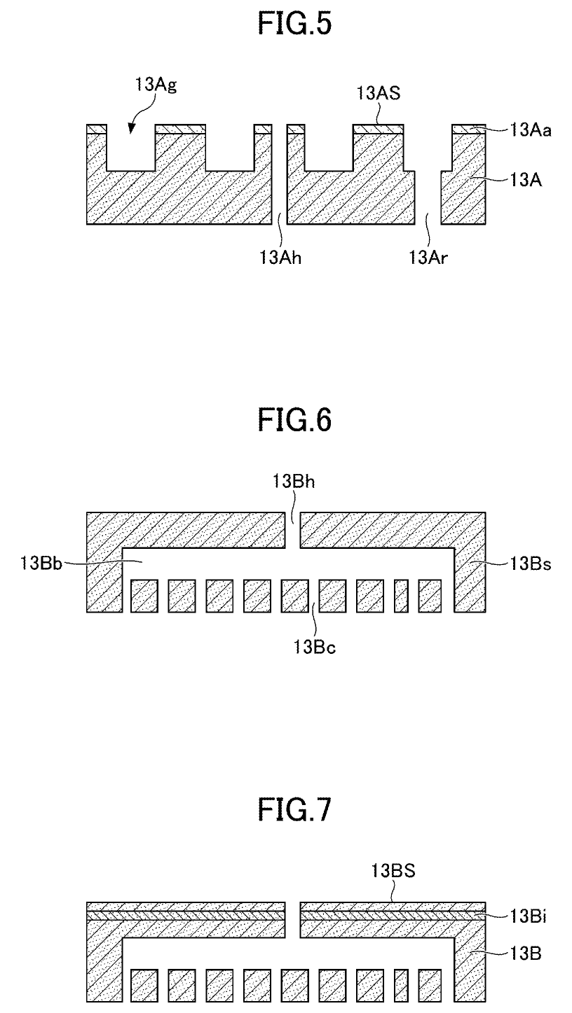

(Step S20) Next, the second plate 13B is formed (second plate forming step). The second plate forming step includes a shape forming step (step S21) and a hydrogen ion-implanted layer forming step (step S22).

[Step S21] First, in the shape forming step, the gas diffusion chamber as an example of the buffer chamber and the plurality of gas inlet ports are formed. FIG. 6 is a cross-sectional view explaining the second plate forming step of the method for manufacturing the showerhead 13 in the plasma processing apparatus 1 as an example of the plasma processing apparatus according to the present embodiment. Specifically, FIG. 6 is a view showing a process of forming the shape of the second plate 13B.

In the shape forming step (step S21), a silicon substrate 13Bs is formed to have a gas diffusion chamber 13Bb, which becomes the gas diffusion chamber 13b, a plurality of gas inlet ports 13Bc, which become the gas inlet ports 13c, and a through-hole 13Bh, which is to be connected to the gas supply port 13a. The through-hole 13Bh constitutes a part of the gas flow path through which a processing gas is caused to flow into the gas diffusion chamber serving as the buffer chamber. The silicon substrate 13Bs may be formed by, for example, laminating layers of silicon, by adhesively joining a plurality of members using a brazing agent, or by thermocompression bonding.

[Step S22] Next, in the hydrogen ion-implanted layer forming step, a hydrogen ion-implanted layer is formed on the silicon substrate that has been shaped in the shape forming step (step S21). FIG. 7 is a cross-sectional view explaining the second plate forming step of the method of manufacturing the showerhead 13 in the plasma processing apparatus 1, which is an example of the plasma processing apparatus according to the present embodiment. FIG. 7 is a view showing a process of forming a hydrogen ion-implanted layer on the silicon substrate that has been shaped.

In the hydrogen ion-implanted layer forming step (step S22), hydrogen is implanted from a surface 13BS. Then, a hydrogen ion-implanted layer 13Bi is formed at a depth of some nanometers from the surface 13BS. The second plate 13B is formed by forming the hydrogen ion-implanted layer 13Bi. Although an example in which hydrogen is used is shown here, helium or the like can be used instead of hydrogen. For example, by using helium instead of hydrogen, a helium-implanted layer may be formed instead of the hydrogen ion-implanted layer 13Bi.

When the process flow up to step S22 has been performed, the second plate 13B is formed. The surface 13BS serves as a joining surface to be joined with the first plate 13A.

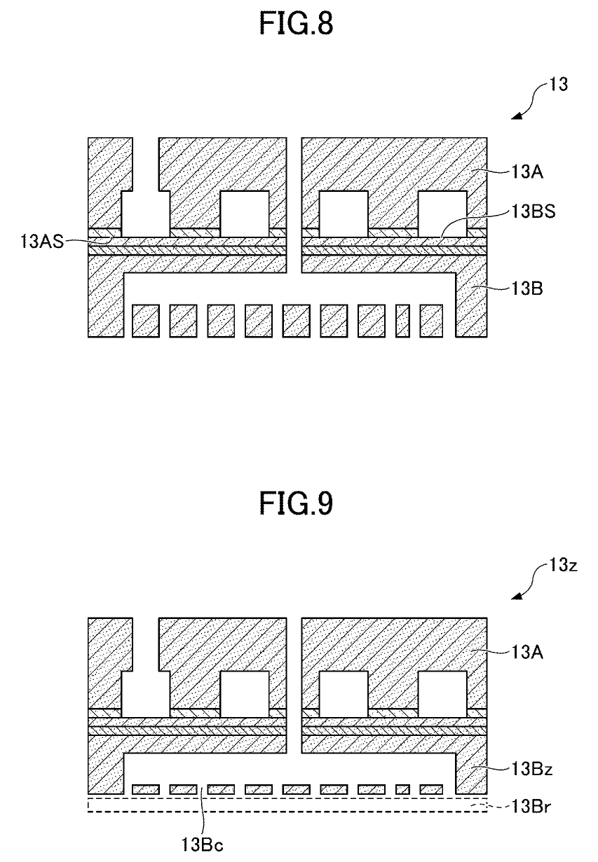

(Step S30) Next, the first plate 13A and the second plate 13B are joined (joining step). The first plate 13A and the second plate 13B are joined by being pressed at a low temperature (normal temperature) while the joining surfaces are activated. FIG. 8 is a cross-sectional view explaining the joining step of the method of manufacturing the showerhead 13 in the plasma processing apparatus 1, which is an example of the plasma processing apparatus according to the present embodiment. Specifically, FIG. 8 is a view showing a process of joining the first plate 13A and the second plate 13B.

Specifically, the joining surface 13AS (first joining surface) of the first plate 13A and the surface 13BS (second joining surface), which is the joining surface of the second plate 13B, are joined.

When the process flow up to step S30 has been performed, the showerhead 13 is formed.

Next, a method of regenerating the showerhead 13 in the plasma processing apparatus 1, which is an example of the plasma processing apparatus according to the present embodiment, will be described. By describing the method of regenerating the showerhead 13, a method of regenerating an electrode plate in the plasma processing apparatus according to the present embodiment will be described.

FIG. 9 is a cross-sectional view explaining a worn showerhead 13z in the plasma processing apparatus 1, which is an example of the plasma processing apparatus according to the present embodiment.

In the showerhead 13, the side of the second plate 13B where the gas inlet ports 13Bc are formed is worn by plasma. The showerhead 13z represents a showerhead 13z worn by plasma. In the showerhead 13z, since the first plate 13A is exposed to no plasma, the first plate 13A incurs a small change in shape. On the other hand, the second plate 13B, especially the side of the second plate 13B where the gas inlet ports 13Bc are formed, is worn due to exposure to plasma. For example, as shown by a dotted-line frame 13Br in FIG. 9, the second plate 13B is worn by plasma. Since a part of the second plate 13B is worn as shown by the dotted-line frame 13Br, the second plate 13B becomes thinner as shown as a second plate 13Bz.

Therefore, in the plasma processing apparatus according to the embodiment, the worn second plate 13Bz is replaced. On the other hand, in the plasma processing apparatus according to the embodiment, the first plate 13A is reused.

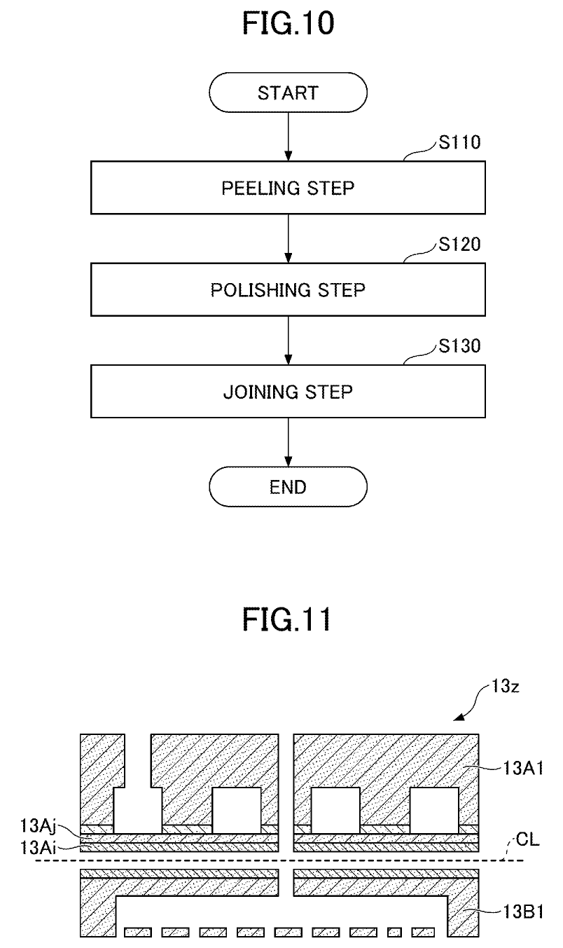

The method of regenerating the showerhead 13 in the plasma processing apparatus 1, which is an example of the plasma processing apparatus according to the embodiment, will be described. By describing a method of regenerating the showerhead 13, the method of regenerating an electrode plate in the plasma processing apparatus according to the present embodiment will be described. FIG. 10 is a flowchart explaining the method of regenerating the showerhead 13 in the plasma processing apparatus 1, which is an example of the plasma processing apparatus according to the present embodiment.

The method of regenerating the showerhead 13 includes a peeling step (step S110) of peeling the first plate 13A of the showerhead 13, and a polishing step (step S120) of polishing the first plate 13A. The method of regenerating the showerhead 13 also includes a joining step (step S130) of joining the polished first plate 13A and a new second plate 13B.

(Step S110) First, the first plate 13A is peeled from the second plate 13B of the showerhead 13. FIG. 11 is a cross-sectional view explaining the method of regenerating the showerhead 13 in the plasma processing apparatus 1, which is an example of the plasma processing apparatus according to the present embodiment. Specifically, FIG. 11 is a view showing a process of peeling the first plate 13A1 from the second plate 13B1 of the worn showerhead 13z.

As shown in FIG. 11, the first plate 13A1 and the second plate 13B1 are separated with the hydrogen ion-implanted layer 13Bi of the second plate 13B as a boundary. In other words, the first plate 13A1 is peeled from the second plate 13B1 using a surface included in the hydrogen ion-implanted layer 13Bi as a cutting surface CL. For example, by heating the showerhead 13z to a temperature of approximately 400°C, peeling is caused to occur in the hydrogen ion-implanted layer 13Bi.

The first plate 13A1 and the second plate 13B1 are separated with the hydrogen ion-implanted layer 13Bi as a boundary. Since the first plate 13A1 and the second plate 13B1 are separated with the hydrogen ion-implanted layer 13Bi as a boundary, the first plate 13A1 includes a hydrogen ion-implanted layer 13Ai, which is a part of the hydrogen ion-implanted layer 13Bi of the second plate 13B. The first plate 13A1 includes a silicon layer 13Aj, which is a silicon layer from the hydrogen ion-implanted layer 13Ai in the second plate 13B to the joining surface. In other words, the plates are peeled in a state in which the hydrogen ion-implanted layer 13Ai and the silicon layer 13Aj, which are silicon layers, remains on the surface of the silicon oxide film 13Aa of the first plate 13A1.

For example, the second plate 13B1 may be dissolved and reused as a material.

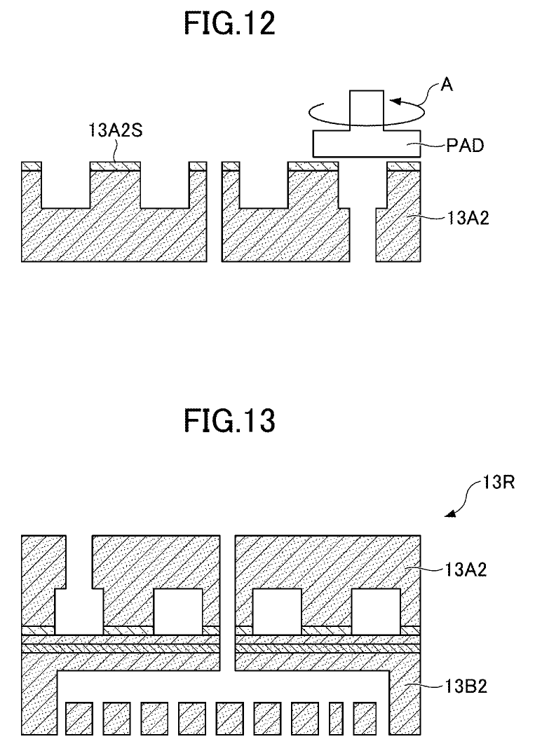

(Step S120) Next, the hydrogen ion-implanted layer 13Ai and the silicon layer 13Aj adhering to the first plate 13A1 are removed by polishing. The joining surface of the first plate 13A1 is planarized by polishing the first plate 13A1. FIG. 12 is a cross-sectional view explaining the method of regenerating the showerhead 13 in the plasma processing apparatus 1, which is an example of the plasma processing apparatus according to the present embodiment. Specifically, FIG. 12 is a view showing a process of forming a joining surface 13A2S by polishing the surface of the first plate 13A1.

For example, the surface of the first plate 13A1 is polished by Chemical Mechanical Polishing (CMP) to remove the adhering hydrogen ion-implanted layer 13Ai and silicon layer 13Aj. Then, the joining surface 13A2S of a first plate 13A2, which is the first plate 13A1 from which the adhering hydrogen ion-implanted layer 13Ai and silicon layer 13Aj are removed, is polished and planarized.

As shown in FIG. 12, the hydrogen ion-implanted layer 13Ai and the silicon layer 13Aj are removed by polishing with a polishing agent (slurry), by rotating a polishing pad PAD. It is preferable to select the polishing agent (slurry) such that the silicon layer is removed selectively with respect to the silicon oxide layer. As a result, the surface of the silicon oxide film 13Aa of the first plate 13A2 can be regenerated again as the joining surface 13A2S.

Wet etching or dry etching may be used to remove the hydrogen ion-implanted layer 13Ai and the silicon layer 13Aj adhering to the first plate 13A1.

(Step S130) Next, the first plate 13A2 regenerated by polishing and a newly formed second plate 13B2 are joined, to form a new showerhead. FIG. 13 is a cross-sectional view explaining the method of regenerating the showerhead 13 in the plasma processing apparatus 1, which is an example of the plasma processing apparatus according to the present embodiment. Specifically, FIG. 13 is a view showing a showerhead 13R regenerated by joining the regenerated first plate 13A2 and the newly formed second plate 13B2.

For the specific joining method, a detailed description is omitted here, with reference made to step S30.

### Summary

According to the plasma processing apparatus according to the present embodiment, thermal damage to the electrode plate can be prevented. According to the plasma processing apparatus according to the present embodiment, by the formation manner using a single material to result in no contact interface, it is possible to prevent damage due to a material difference.

For example, when an electrode plate is formed of a cooling plate composed of metal and a ceiling plate composed of silicon, thermal stress is applied to the ceiling plate due to a difference in linear expansion between the metal and silicon, which might damage the electrode plate. In addition, when the electrode plate is formed of a cooling plate composed of metal and a ceiling plate composed of silicon, there is a high thermal contact resistance between the cooling plate and the ceiling plate, because replacement is assumed. When there is a high thermal contact resistance, a temperature difference occurs between the parts. When there is a high temperature difference between the parts, the electrode plate might be damaged due to a difference in thermal expansion.

In particular, when the power of a high-frequency signal becomes a high power of approximately some tens of kilowatts in a plasma processing apparatus, the upper part of the electrode plate is cooled by the cooling plate and shrinks, while the plasma-exposed surface expands due to the heat of the plasma. Therefore, in the plasma processing apparatus, when the power becomes high, the electrode plate might deform into a downward sagging shape and be broken.

In addition, when the ceiling plate expands laterally due to the heat of the plasma, it may be broken by the clamp part.

Since the electrode plate of the plasma processing apparatus according to the present embodiment is formed integrally using a single material composed of silicon, the temperature difference between the upper part and the lower part can be reduced with elimination of the thermal resistance at the interface. Furthermore, since the electrode plate of the plasma processing apparatus according to the present embodiment is formed integrally using a single material composed of silicon, no clamp structure is necessary. Since no clamp structure is necessary, the electrode plate of the plasma processing apparatus according to the present embodiment can be prevented from being broken by clamping.

For example, the result of simulative evaluation of a case where a heat transfer fluid controlled to a temperature of 120°C was used and an input of heat from a plasma was 1,500 watts will be described.

The electrode plate of the plasma processing apparatus according to the present embodiment had a temperature of 126.4°C on the plasma processing surface, that is, a temperature difference of 6.4 degrees. The electrode plate of the plasma processing apparatus according to the present embodiment experienced a maximum displacement of 0.01 millimeters.

On the other hand, when a silicon ceiling plate and a metal cooling plate were used, the surface temperature of the silicon ceiling plate was 147.5°C, that is, the temperature difference was 27.5 degrees. In addition, when the silicon ceiling plate and the metal cooling plate were used, the maximum displacement of the silicon ceiling plate was 0.365 millimeters.

According to the electrode plate of the plasma processing apparatus according to the present embodiment, the surface temperature of the electrode plate can be adjusted to be close to the temperature of the heat transfer fluid. In other words, according to the electrode plate of the plasma processing apparatus according to the present embodiment, the temperature difference between the upper part and the lower part can be reduced. Further, according to the electrode plate of the plasma processing apparatus of the present embodiment, deformation of the electrode plate can be reduced.

Further, it is possible to reduce costs involved in the plasma processing apparatus of the present embodiment, in which the electrode plate is composed of a single material and has no contact interface, by selectively separating a part that has been worn due to plasma exposure and adhesively joining a part again.

The plasma processing apparatus of the present embodiment disclosed herein should be considered exemplary and non-restrictive in all respects. The foregoing embodiments can be modified and improved in various forms without departing from the scope and the spirit of the appended claims. The particulars described in the foregoing embodiments can be configured in other forms to the extent to which no contradiction occurs, and can be combined with each other to the extent to which no contradiction occurs.

The present disclosure provides a technique for preventing thermal damage to an electrode plate.

What is claimed is:

1. A plasma processing apparatus, comprising:
an electrode plate disposed to face a substrate mounting table across a processing space,
wherein the electrode plate includes:
a first plate that is composed of silicon, and in which a refrigerant flow path is formed; and
a second plate that is composed of silicon, and in which a buffer chamber configured to supply a processing gas into the processing space is provided, and
the electrode plate is formed integrally by joining the first plate and the second plate.

2. The plasma processing apparatus according to claim 1,
wherein the second plate includes a hydrogen ion-implanted layer toward a side of the second plate on which a joining surface of the second plate to be joined with the first plate is present.

3. The plasma processing apparatus according to claim 1,
wherein the first plate includes a silicon oxide layer on a joining surface of the first plate to be joined with the second plate.

4. The plasma processing apparatus according to claim 1,
wherein the first plate includes a gas flow path through which the processing gas is caused to flow into the buffer chamber.

5. The plasma processing apparatus according to claim 4,
wherein the gas flow path is a through-hole penetrating the first plate.

6. A method of manufacturing an electrode plate disposed in a plasma processing apparatus such that the electrode plate faces a substrate mounting table across a processing space, the method comprising:
(a) forming a first plate, including forming a silicon oxide film on a first joining surface of a silicon substrate, and forming a refrigerant flow path in the first joining surface;
(b) forming a second plate, including forming a buffer chamber configured to supply a processing gas into the processing space, and forming a hydrogen ion-implanted layer from a side of a second joining surface of the second plate; and
(c) joining the first plate and the second plate by joining the first joining surface and the second joining surface.

7. A method of manufacturing an electrode plate disposed in a plasma processing apparatus such that the electrode plate faces a substrate mounting table across a processing space, the method comprising:
(a) forming a first plate, including forming a silicon oxide film on a first joining surface of a silicon substrate; and forming a refrigerant flow path in the first joining surface;
(b) forming a second plate, including forming a buffer chamber configured to supply a processing gas into the processing space, and forming a helium-implanted layer from a side of a second joining surface of the second plate; and
(c) joining the first plate and the second plate by joining the first joining surface and the second joining surface.

8. The method of manufacturing an electrode plate according to claim 6,
wherein in the (c), the first joining surface and the second joining surface are joined by being pressed at normal temperature.

9. A method of regenerating an electrode plate formed integrally by joining a first plate that is composed of silicon and in which a refrigerant flow path is formed and a second plate that is composed of silicon and in which a buffer chamber configured to supply a processing gas into a processing space is provided, the method comprising:
(a) separating the first plate from the second plate with a hydrogen ion-implanted layer, which is provided in the second plate, used as a boundary;
(b) polishing a joining surface of the first plate; and
(c) joining the polished first plate and the second plate that is newly prepared.

10. The method of regenerating an electrode plate according to claim 9,
wherein in the (b), the joining surface is polished by Chemical Mechanical Polishing (CMP).
